(19) United States
(12) Patent Application Publication
(10) Pub. No.: US 2014/0091440 A1
(43) Pub. Date: Apr. 3, 2014

(54) SYSTEM IN PACKAGE WITH EMBEDDED RF DIE IN CORELESS SUBSTRATE

(71) Applicants: Vijay K. NAIR, Mesa, AZ (US); John S. GUZEK, Chandler, AZ (US); Johanna M. SWAN, Scottsdale, AZ (US)

(72) Inventors: Vijay K. NAIR, Mesa, AZ (US); John S. GUZEK, Chandler, AZ (US); Johanna M. SWAN, Scottsdale, AZ (US)

(21) Appl. No.: 13/631,982

(22) Filed: Sep. 29, 2012

(51) Int. Cl. H01L 23/60; H01L 21/50

(52) U.S. Cl. 257/659; 438/107; 257/E23.002; 257/E21.499

(57) ABSTRACT

Electronic assemblies and their manufacture are described. One assembly includes a coreless substrate comprising a plurality of dielectric layers and electrically conductive pathways, the coreless substrate including a first side and a second side opposite the first side. The assembly includes a first die embedded in the coreless substrate, the first die comprising an RF die, the first die positioned in a dielectric layer that extends to the first side of the coreless substrate. The assembly includes a second die positioned on first side, the second die positioned on the first die. In another aspect, a molding material may be positioned on the die side, wherein the first die and the second die are covered by the molding material. In another aspect, an electrical shielding layer may be positioned over the first side. Other embodiments are described and claimed.

### BACKGROUND

As electronic devices are made smaller and smaller and wireless communication needs increase, conventional assemblies including an radio frequency die (RF die) positioned on a package substrate are of a thickness that makes the formation of low profile small form factor wireless communication devices difficult to achieve.

### BRIEF DESCRIPTION OF THE DRAWINGS

Embodiments are described by way of example, with reference to the accompanying drawings, which are not drawn to scale.

FIG. 1 illustrates an assembly including a multilayer substrate including an embedded RF die, in accordance with certain embodiments.

FIG. 2 illustrates an assembly including a multilayer substrate including an embedded RF die and another embedded die, in accordance with certain embodiments.

FIG. 3 illustrates an assembly including a multilayer substrate including an embedded RF die and a flip chip die on a surface of the substrate, in accordance with certain embodiments.

FIG. 4 illustrates an assembly including an embedded RF die and a flip chip die, with a gap between the flip chip die and a surface of the substrate, in accordance with certain embodiments.

FIG. 5 is a flowchart of operations for forming an assembly including a multilayer substrate including an embedded RF die, in accordance with certain embodiments.

FIG. 6 illustrates an electronic system arrangement in which embodiments may find application.

### DETAILED DESCRIPTION

Reference below will be made to the drawings wherein like structures may be provided with like reference designations. In order to show the structures of various embodiments most clearly, the drawings included herein include diagrammatic representations of electronic devices and various components. Thus, the actual appearance of the fabricated structures may appear different while still incorporating the claimed structures of the illustrated embodiments. Moreover, the drawings may show only the structures necessary to understand the illustrated embodiments. Additional structures known in the art have not been included to maintain the clarity of the drawings.

RF (radio frequency) package assemblies have been formed to include one or more RF die structures positioned on a substrate, together with accompanying components including, but not limited to, power amplifiers, switches, and other devices.

Certain embodiments relate to an assembly structure including an RF die embedded in a substrate, and a component positioned on the RF die. Certain embodiments also relate to the use of multiple embedded RF die structures and multiple components. Still other embodiments relate to methods for manufacturing assembly structures including embedded RF die structures.

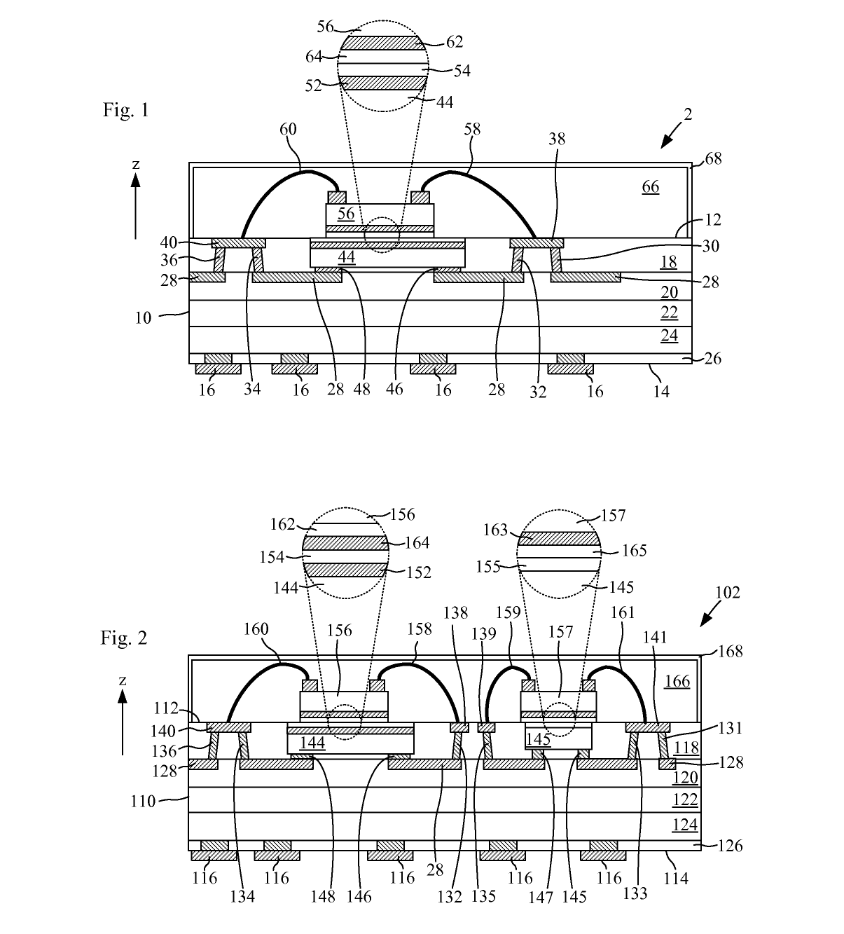

FIG. 1 is a cross-sectional view of an embodiment comprising an assembly 2 including a substrate 10. The substrate 10 as illustrated is coreless and includes a first side 12 and a second side 14. As illustrated in the embodiment of FIG. 1, the first side 12 may be referred to as a device mounting side because electrical components (including, but not limited to, amplifiers, switches, processors) may be positioned thereon. The second side 14 may be referred to as a land side and includes a plurality of interconnection pads 16 thereon to which electrical connections to another device such as a board (not shown in FIG. 1) can be made. The substrate 10 includes a plurality of layers including dielectric layers 18, 20, 22, 24, 26. Layer 26 may be a solder resist layer. The substrate 10 also includes electrically conductive pathways formed to route electrical signals within the substrate 10. FIG. 1 shows an example of an electrically conductive pathway in dielectric layer 18 and extending into dielectric layer 20, including a patterned metal layer 28 and electrically conductive vias 30, 32, 34, 36 extending to pad metal regions 38, 40 that serve as pads for wire bonding. The metal path layout as illustrated in FIG. 1 is an example of one layout and a variety of modifications may be made. Metal pathways through most of the dielectric layers are not shown for simplification. In the embodiment of FIG. 1, the substrate 10 may be formed using bumpless build-up layer (BBUL) technology, where dielectric layers and metal layers are deposited and laminated to form a bumpless build-up layer coreless (BBUL-C) package.

As illustrated in the embodiment of FIG. 1, an RF die 44 is embedded within the upper dielectric layer 18 of the substrate 10. The RF die 44 may include a metallization layer 52 positioned on a backside surface thereof. The metallization layer may be a single metal layer or may be a stack of metal layers. Electrical connections to and from the RF die 44 are made on the active side of the RF die 44 through connections 46, 48. For simplicity only two connections 46, 48 are illustrated. A die attach film 54 formed from, for example, a polymer, may be positioned on the metallization layer 52, with the metallization layer 52 being positioned between the RF die 44 and the die attach film 54.

Another component such as a die 56 may be positioned on the substrate 10 on the die attach film 54 on the RF die 44. The die 56 may in certain embodiments comprise a second RF die that is wire bonded to the substrate 10 at pad regions 38, 40 through wire bonds 58, 60. The die 56 may also include a metallization layer 62 and a die attach film 64, with the metallization layer 62 positioned between the die attach film 64 and the die 56, and with the die attach film 64 coupled to the die attach film 54 on the RF die 44. It should be appreciated that depending on the specific die structures and/or components utilized, in certain embodiments one or more of the die attach films 54, 64, and metallization layers 52, 62 may be modified or omitted. It should also be appreciated that the various layers illustrated in FIG. 1 are not necessarily drawn to scale, need not be uniform in thickness, and may vary from the illustrated embodiment.

As illustrated in FIG. 1, the RF die 44 is embedded within the substrate 10 and the die 56 is positioned on the RF die 44, separated by metallization layers 52, 62 and attachment film layers 54, 64. When viewed from above, the blown-up portion of FIG. 1 illustrates the relationship of the various layers, with the attachment film layers 54 and 64 being in contact with one another. A molding layer 66 such as a polymer may be formed to cover the substrate surface, including the die 56 and the wire bonds 58, 60 coupled to the pad regions 38, 40. Suitable conformal shielding 68 may also be formed on the sides and top of the molding layer 66, to shield electromagnetic (EM) noise. In order to minimize the height of an assembly, the connection to a board may be made using a land grid array (LGA) using the interconnection pads 16. Other interconnection configurations, including, but not limited to, ball grid array (BGA) may also be used. In certain embodiments, the RF die 44 may include baseband and media access control circuitry (BB-MAC). In addition, in certain embodiments, the component 56 may be selected from a structure including, but not limited to, another RF die or an analog die component.

By forming an assembly including a package structure such as illustrated in FIG. 1, one or more of the following advantages may be present in certain embodiments. First, by embedding the RF die 44 in the substrate 10, the height of the package may be decreased when compared with packages having such an RF die that is not embedded within the substrate. Second, by embedding the RF die 44, the signal length may be decreased. Third, the design illustrated in FIG. 1 also provides in-situ shielding of the RF die 44. Fourth, by positioning the die 56 on the RF die 44 as illustrated in FIG. 1, for example, the substrate 10 width may be decreased and the interconnection length may be decreased when compared with a package having die structures in a different configuration.

FIG. 2 illustrates a cross-sectional view of an assembly 102 including a substrate 110, in accordance with certain embodiments. The substrate 110 is coreless and includes a first side 112 and a second side 114. The substrate 110 comprises a first side 112 including electrical components (including, but not limited to, amplifiers, switches, processors) positioned thereon. The second side 114 includes a plurality of interconnection pads 116 thereon to which electrical connections to another device such as a board (not shown in FIG. 2) can be made. The substrate 110 may include a plurality of layers including dielectric layers 118, 120, 122, 124, 126. Layer 126 may be a solder resist layer. The dielectric layers need not be uniform in thickness. The substrate 110 includes electrically conductive pathways formed to route electrical signals. FIG. 2 shows an example of an electrically conductive pathway in dielectric layer 118 and extending into dielectric layer 120, including a patterned metal layer 128 within dielectric layer 126, as well as electrically conductive vias 131, 132, 133, 134, 135, and 136 that contact the metal layer 128, and pad regions 138, 139, 140, and 141 that serve as wire bonding regions. The electrically conductive pathway as illustrated in FIG. 2 is an example of one layout and a variety of modifications may be made. Electrically conductive pathways (including, for example, patterned metal layers, vias, and other metal regions such as described above) may extend through the other dielectric layers but are not shown for simplification. The substrate 110 may be formed using bumpless build-up layer (BBUL) technology to form a bumpless build-up layer coreless (BBUL-C) package. The substrate 110 may include a molding layer 166 and conformal shielding 168 positioned thereon.

In certain embodiments, a plurality of die structures may be embedded within a substrate. As illustrated in the embodiment of FIG. 2, RF die 144 and die 145 are embedded within the substrate 110 in the upper dielectric layer 118. In one embodiment, the RF die 144 including radio frequency integrated circuitry (RFIC) including baseband and media access control circuitry (BB-MAC). The die 145 may in one embodiment be an integrated passive device (IPD), for example, including circuitry that provides for RF matching and frequency tuning functions for a power amplifier. Metallization layer 152 and die attach film 154 may be provided on the RF die 144, and die attach film 155 may be provided on the die 145. The electrical connections to and from the RF die 144 are made on the active side in the embodiment illustrated in FIG. 2, through the connections 146, 148. For simplicity two connections 146, 148 are illustrated, although embodiments may include a greater number of connections. A die attach film 154 may be positioned on the metallization layer 152, so that the metallization layer 152 is positioned between the RF die 144 and the die attach film 154.

A component such as a die 156 which may be, for example, an RF power amplifier die, may be positioned on the substrate 110 on the die attach film 154 on the RF die 144 that is embedded in the substrate. The die 156 may in certain embodiments be wire bonded to the substrate 110 at pad regions 138, 140 through wire bonds 158, 160. The die 156 may also include a metallization layer 162 and a die attach film 164, with the die attach film 164 coupled to the die attach film 154 on the RF die 144, as illustrated in the left side blown-up portion of FIG. 2.

A component such as a die 157 which may be, for example, an RF switch die, may be positioned on the substrate 110 on the die attach film 155 on the die 145 that is embedded in the substrate 110, as illustrated in the right side blown-up portion of FIG. 2. The die 157 may in certain embodiments be wire bonded to the substrate 110 at pad regions 139, 141 through wire bonds 159, 161. The die 157 such as the RF switch die may also include a metallization layer 163 and a die attach film 165, with the metallization layer 163 positioned between the die attach film 165 and the die 157, with the die attach film 165 coupled to the die attach film 155 on the RF die 144.

As assembly in accordance with the embodiment illustrated in FIG. 2 may include a variety of RF components either embedded in or positioned on a device attachment side of a multilayer substrate. Such an assembly enables the formation in certain embodiments of a complete RF transceiver package.

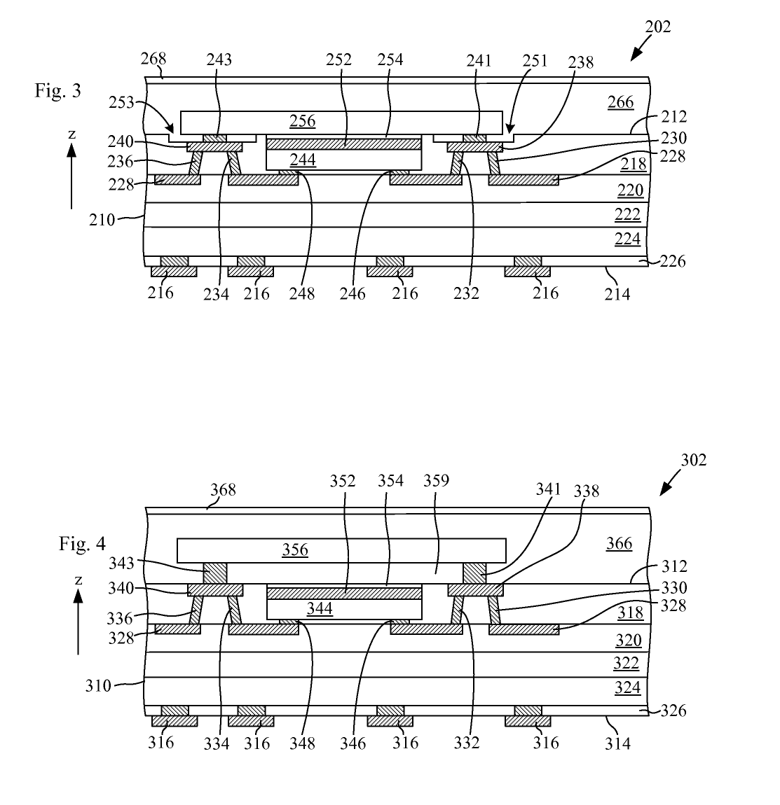

FIG. 3 illustrates a cross-sectional view of an assembly 202 comprising a substrate 210 including a flip chip die 256 positioned on an embedded RF die 244, in accordance with certain embodiments. The substrate 210 is coreless and includes a first side 212 and a second side 214. The first side 212 may include electrical components (including, but not limited to, amplifiers, switches, processors) positioned thereon. The second side 214 includes a plurality of interconnection pads 216 thereon to which electrical connections to another device such as a board can be made. The substrate 210 includes a plurality of layers including dielectric layers 218, 220, 222, 224, 226. Layer 226 may be a solder resist layer. The substrate 210 also includes electrically conductive pathways formed to route electrical signals within the substrate 210. FIG. 3 shows an example of an electrically conductive pathway in dielectric layer 218 and extending into dielectric layer 220, including a patterned metal layer 228 and electrically conductive vias 230, 232, 234, 236 extending to pad metal regions 238, 240. The metal path layout as illustrated in FIG. 3 is an example of one layout and a variety of modifications may be made. Metal pathways in the other dielectric layers are not shown for simplification. The substrate 210 may be formed using bumpless build-up layer (BBUL) technology, where metal and dielectric layers are deposited and laminated to form a bumpless build-up layer coreless (BBUL-C) package. The substrate 210 may include a molding layer 266 and conformal shielding 268 positioned thereon.

In the embodiment illustrated in FIG. 3, flip chip die 256 is positioned on the die attach film 254 on the RF die 244 that is embedded in the upper dielectric layer 218. The RF die 244 may include a metallization layer 252 positioned on a backside surface thereof. Electrical connections to the RF die 244 may be made on the active side of the RF die through electrical connections 246, 248. The flip chip die 256 may be electrically coupled to the RF die 244 through, for example, electrical connections 241, 243 to pad regions 238, 240. The pad regions 238, 240 may be recessed to minimize the vertical height of the assembly. As illustrated in FIG. 3, a recessed region 251, 253 is formed in the dielectric layer 226 on the first side 212 and the electrical connections 241, 243 extend through the recessed region 251, 253 between the flip chip die 256 and the pad regions 238, 240. Depending on the size and exact configuration of the recessed region 251, 253, a die structure may in certain embodiments be at least partially positioned therein and may be at least partially embedded within the substrate 210.

FIG. 4 illustrates a cross-sectional view of an assembly 302 in some ways similar to that of FIG. 3, including a substrate 310 and a flip chip die 356 positioned on an embedded RF die 344, in accordance with certain embodiments. The substrate 310 is coreless and includes a first side 312 that may include electrical components (including, but not limited to, amplifiers, switches, processors) positioned thereon, and a second side 314 including a plurality of interconnection pads 316 thereon to which electrical connections to another device such as a board can be made. The substrate 310 includes a plurality of layers including dielectric layers 318, 320, 322, 324, 326. Layer 26 may be a solder resist layer. The substrate 310 also includes electrically conductive pathways formed to route electrical signals within the substrate 310. FIG. 4 shows an example of an electrically conductive pathway in dielectric layer 318 and extending into dielectric layer 320, including a patterned metal layer 328 and electrically conductive vias 330, 332, 334, 336 extending to pad metal regions 338, 340. The metal path layout as illustrated in FIG. 4 is an example of one layout and a variety of modifications may be made. Metal pathways in most of the dielectric layers are not shown for simplification. The substrate 310 may be formed using bumpless build-up layer (BBUL) technology, where metal and dielectric layers are deposited and laminated to form a bumpless build-up layer coreless (BBUL-C) package. The substrate 310 may include a molding layer 366 and conformal shielding 368 positioned thereon.

In the embodiment illustrated in FIG. 4, the flip chip die 356 is electrically coupled to the RF die 344 that is embedded in the upper dielectric layer 318. The RF die 344 may include a metallization layer 352 and die attach film 354 on a backside surface thereof. Electrical connections to the RF die 344 may be made on the active side of the die through electrical connections 346, 348 coupled to the patterned metal layer 328. The flip chip die 356 may be electrically coupled to the RF die 344 through, for example, electrical connections 341, 343 to pad regions 338, 340. The pad regions 338, 340 extend to the surface on side 312 of the substrate 310. Other layers on the flip chip die 356 (for example, metallization) may also be present but are not illustrated for simplicity. The flip chip die 356 is positioned with a gap 359 between the die 356 and the surface on the side 314 of the substrate 310. Such a gap 359 acts to minimize the electrical interference between the flip chip die 356 and the RF die 344. The size of the gap 359 between the flip chip die 356 and the surface on side 314 of the substrate 310 may be controlled by the height of the electrical connections 341, 343.

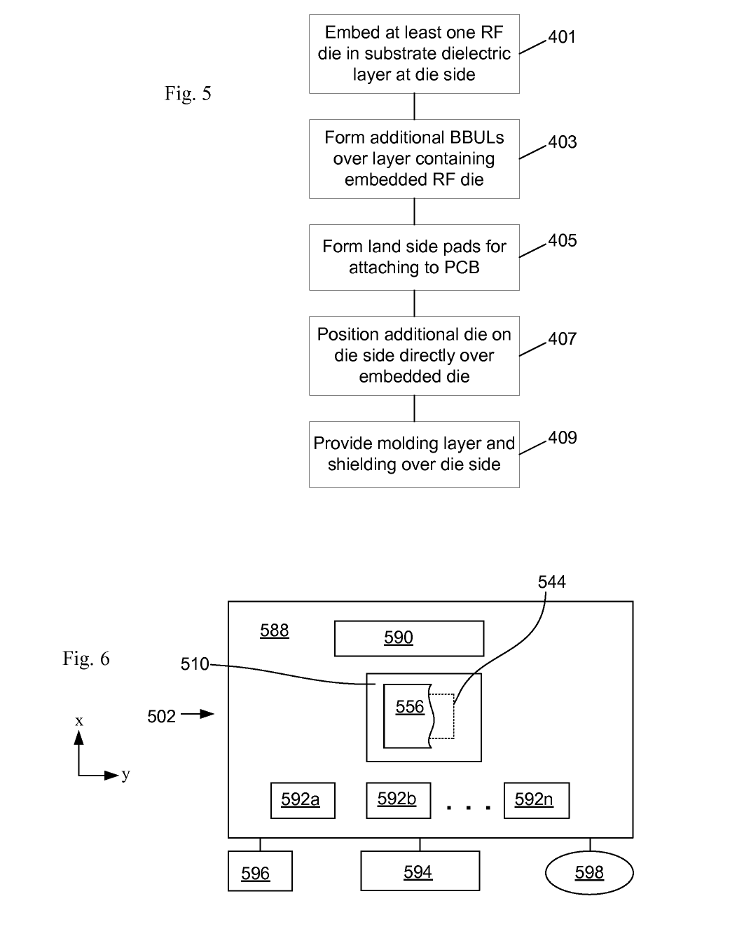

FIG. 5 illustrates a flowchart of operations for forming an assembly including an embedded RF die, in accordance with certain embodiments. Box 401 is embedding at least on RF die in a substrate dielectric layer at the die side of the substrate. Any suitable processing operations may be used, including, but not limited to, BBUL-C processing. In a BBUL-C process, the RF die may be provided on a surface, then the dielectric layer may be build-up around the RF die. In certain embodiments, contact openings may then be formed through the dielectric layer, and filled with a metal to form electrical pathways for connecting to the RF die. Box 403 is forming additional dielectric and metal layers over the dielectric layer containing the RF die. In a BBUL process, such layers be laminated onto the structure (with suitable electrical pathways formed) to yield a multilayer substrate. Box 405 is forming land pads on the multilayer substrate for attaching the substrate to a printed circuit board (PCB). Box 407 is positioning an additional die on the device attachment side (opposite the side the land pads are formed on), with the additional die being positioned so that at least part of the additional die is positioned directly over the embedded die. Such a layout serves to minimize the electrical connection distance between the embedded die and the additional die. Box 409 is providing a molding layer and shielding on the device attachment side over the additional die and the embedded die, to provide protection and electrical shielding. It should be appreciated that various additions, subtraction, and/or modifications may be made to the above operations described in connection with FIG. 4, within the scope of various embodiments. For example, in box 407, the additional die may be part of a package substrate assembly that is sized to fit on the die attachment side over the embedded RF die. In addition, certain embodiments may relate to a subset of the operations specified in FIG. 4, independent of other operations specified in FIG. 4.

Embodiments as described herein may provide one or more of the following advantages. First, the embedded structure of the RF die and additional die structure(s) enables the package substrate to have a smaller height (z-direction), with certain embodiments including a substrate including a molding layer having a total height that is less than 1 mm. Second, by stacking components on the embedded die(s), the package substrate may have smaller lateral dimensions (x-y directions). Such configurations may in certain embodiments enable as much as a 50 percent decrease in the lateral dimensions. Third, by positioning RF dies on top of each other, shorter and reliable connections may be made, which minimizes the RF loss and improves the RF performance. Fourth, depending on the type of component positioned in or on the substrate, heterogeneous integration of multiple technologies may be enabled in a single package substrate assembly. Fifth, an RF transceiver can be custom tailored on a single package substrate. In addition, a metallization layer such as that formed on one or more of the die structures in FIGS. 1-4 may act to minimize electrical interference.

Assemblies including structures formed as described in embodiments above may find application in a variety of electronic components. FIG. 6 schematically illustrates one example of an electronic system assembly in which aspects of described embodiments may be embodied. Other embodiments need not include all of the features specified in FIG. 6, and may include alternative features not specified in FIG. 6.

The assembly 502 of FIG. 6 may include at least one embedded RF die 544 in a substrate 510. The RF die 544 may be electrically coupled to an additional die 556 positioned on the RF die. As illustrated in FIG. 6, a portion of the additional die 556 is cut away to illustrate the RF die 544 (referenced by a dotted line to indicate it is embedded in the substrate 510). The RF die 544 and additional die 556 positioned thereon may be configured as in certain embodiments described above, for example, including those illustrated in FIGS. 1, 3 and 4. While only one embedded RF die and one additional die are illustrated in FIG. 6, embodiments may include multiple embedded dies and multiple additional dies (RF dies or other types of die structures) on the substrate, for example, as described in connection with FIG. 2. By locating various components (for example, CPU, amplifier, etc.) in or on the package substrate, the size of the system may be decreased.

The substrate 510 may be coupled to a printed circuit board 588. The assembly 502 may further include other components including, but not limited to, memory 590 and one or more controllers 592a, 592b . . . 592n, which are also disposed on the board 588. The board 588 may be a single layer or multi-layered board which has a plurality of conductive lines that provide communication between the circuits in the package substrate 510 and other components mounted to the board 588. The board 588 may in certain embodiments comprise cards such as a daughter card or expansion card. Certain components may also be seated in sockets or may be connected directly to the board. Various components may also be integrated in the same package. A display 594 may also be included.

Any suitable operating system and various applications may execute and reside in the memory 590. The content residing in memory 590 may be cached in accordance with known caching techniques. Programs and data in memory 590 may be swapped into storage 596 as part of memory management operations. The system assembly 502 may comprise any suitable computing device, including, but not limited to, a mainframe, server, personal computer, workstation, laptop, handheld computer, netbook, ultrabook, tablet, book reader, handheld gaming device, handheld entertainment device (for example, MP3 (moving picture experts group layer-3 audio) player), PDA (personal digital assistant) smart phone or other telephony device (wireless or wired), network appliance, virtualization device, storage controller, network controller, router, etc.

The controllers 592a, 592b . . . 592n may include one or more of a system controller, peripheral controller, memory controller, hub controller, I/O (input/output) bus controller, video controller, network controller, storage controller, communications controller, etc. For example, a storage controller can control the reading of data from and the writing of data to the storage 596 in accordance with a storage protocol layer. The storage protocol of the layer may be any of a number of known storage protocols. Data being written to or read from the storage 596 may be cached in accordance with known caching techniques. A network controller can include one or more protocol layers to send and receive network packets to and from remote devices over a network 598. The network 598 may comprise a Local Area Network (LAN), the Internet, a Wide Area Network (WAN), Storage Area Network (SAN), etc. Embodiments may be configured to transmit and receive data over a wireless network or connection. In certain embodiments, the network controller and various protocol layers may employ the Ethernet protocol over unshielded twisted pair cable, token ring protocol, Fibre Channel protocol, etc., or any other suitable network communication protocol.

It should be appreciated that many changes may be made within the scope of the embodiments described herein. The term die as used herein refers to a workpiece that is transformed by various process operations into a desired electronic device. A die is usually singulated from a wafer, and may be made of semiconducting, non-semiconducting, or combinations of semiconducting and non-semiconducting materials. Terms such as “first”, “second”, and the like, if used herein, do not necessarily denote any particular order, quantity, or importance, but are used to distinguish one element from another. Terms such as “top”, bottom”, “upper”, “lower”, “over”, “under”, and the like are used for descriptive purposes and to provide a relative position and are not to be construed as limiting. Embodiments may be manufactured, used, and contained in a variety of positions and orientations.

In the foregoing Detailed Description, various features are grouped together for the purpose of streamlining the disclosure. This method of disclosure is not to be interpreted as reflecting an intention that the claimed embodiments of the invention require more features than are expressly recited in each claim. Rather, as the following claims reflect, inventive subject matter may lie in less than all features of a single disclosed embodiment. Thus the following claims are hereby incorporated into the Detailed Description, with each claim standing on its own as a separate preferred embodiment.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art.

What is claimed:

1. An assembly comprising:
a coreless substrate comprising a plurality of dielectric layers and electrically conductive pathways, the coreless substrate including a first side and a second side opposite the first side;
a first die embedded in the coreless substrate, the first die comprising an RF die, the first die positioned in a dielectric layer that extends to the first side of the coreless substrate; and
a second die positioned on first side, the second die positioned on the first die.

2. The assembly of claim 1, further comprising;
a molding material positioned on the die side, wherein the first die and the second die are covered by the molding material; and
an electrical shielding layer positioned over the first side.

3. The assembly of claim 1, further comprising:
a third die embedded in the coreless substrate, the third die positioned in the same dielectric layer as the first die; and
a fourth die positioned on the third die on the first side of the coreless substrate.

4. The assembly of claim 1, further comprising a plurality of interconnect pads on the land side of the coreless substrate, and a printed circuit board, wherein the coreless substrate is electrically coupled to the printed circuit board through the interconnect pads.

5. The assembly of claim 1, wherein the first die includes an active side and a back side, the active side of the first die positioned between the back side of the first die and the second side of the coreless substrate.

6. The assembly of claim 1, further comprising wire bonds electrically coupling the second die to the coreless substrate.

7. The assembly of claim 1, wherein the second die comprises a power amplifier, and wherein the second die is electrically coupled to the first die.

8. The assembly of claim 1, wherein the second die includes an active side and a back side, wherein the back side of the second die faces the back side of the first die.

9. The assembly of claim 1, wherein at least part of the second die is positioned directly over the first die.

10. The assembly of claim 1, wherein the second die includes an active side and a back side, and wherein the active side of the second die faces the back side of the first die.

11. The assembly of claim 1, further comprising a gap between the second die and the back side of the coreless substrate.

12. The assembly of claim 5, the first die including a metallization layer on the back side thereof.

13. An assembly comprising:
a coreless substrate including a first side and a second side;
a first die embedded in a dielectric layer in the coreless substrate, the first die comprising an RF die;
a second die positioned on the first side of the coreless substrate and electrically coupled to the first die;
wherein the first die is separated from the second side by a plurality of dielectric layers; and
wherein the second die is aligned with the first die so that when viewed from above, the second die covers at least part of the first die.

14. The assembly of claim 13, further comprising:
a molding material positioned on the first side, wherein the first die and the second die are covered by the molding material; and
an electrical shielding structure coupled to the molding material on the first side.

15. The assembly of claim 13;
the first die including a metallization layer and a die attach film thereon; and
the second die including a metallization layer and a die attach film thereon;
wherein the die attach film of the second die is positioned in contact with the die attach film of the first die;

16. The assembly of claim 13, wherein the first die is positioned in a dielectric layer that extends to the first side of the coreless substrate.

17. The assembly of claim 13, further comprising a third die embedded in the dielectric layer, and a fourth die positioned on the die attachment side of the coreless substrate.

18. A method comprising:
embedding a first die comprising an RF die in a dielectric layer in a coreless substrate, the coreless substrate including a first side and a second side opposite the first side, the first die positioned in a dielectric layer that extends to the first side;
positioning a second die on the first side of the coreless substrate, the second die positioned over the first die;
forming a molding layer on the first side of the substrate, the molding layer covering the first die and the second die; and
providing an electrical shielding layer coupled to the molding layer on the die side.

19. The method of claim 18, further comprising embedding a third die in the same dielectric layer as the first die;
positioning a fourth die on the first side of the coreless substrate, the fourth die positioned on the third die.

20. The method of claim 18, further comprising positioning the first die and the second die so that an active side of the first die faces the second side of the coreless substrate and a back side of the first die faces the second die.

21. The method of claim 18, further comprising positioned the second die so that a back side of the second die faces a back side of the first die.

22. The method of claim 18, further comprising positioning the second die so that an active side of the second die faces the back side of the first die.

23. The method of claim 18, further comprising a recessed region on the first side, wherein a plurality of electrical connections from the second die to the coreless substrate are made in the recessed region.

24. The method of claim 18, wherein the second die is spaced apart from the first side of the coreless substrate.
